(19) United States
(12) Patent Application Publication
(10) Pub. No.: US 2023/0253471 A1
(43) Pub. Date: Aug. 10, 2023

(54) NITRIDE SEMICONDUCTOR DEVICE AND METHOD OF MANUFACTURING NITRIDE SEMICONDUCTOR DEVICE

(71) Applicant: ROHM CO., LTD., Kyoto (JP)

(72) Inventor: Tsuyoshi TACHI, Kyoto (JP)

(73) Assignee: ROHM CO., LTD., Kyoto (JP)

(21) Appl. No.: 18/149,170

(22) Filed: Jan. 3, 2023

(30) Foreign Application Priority Data
Feb. 10, 2022 (JP) 2022-019438

(51) Int. Cl. H01L 29/47; H01L 23/31; H01L 29/20; H01L 29/205; H01L 29/40; H01L 29/778; H01L 29/66

(52) U.S. Cl. CPC H01L 29/475; H01L 23/3171; H01L 29/2003; H01L 29/205; H01L 29/402; H01L 29/7786; H01L 29/401; H01L 29/66462

(57) ABSTRACT

A nitride semiconductor device includes: an electron transit layer composed of a nitride semiconductor; an electron supply layer formed on the electron transit layer and composed of a nitride semiconductor having a bandgap larger than that of the electron transit layer; a gate layer formed on a portion of the electron supply layer and composed of a nitride semiconductor containing acceptor-type impurities; a gate electrode formed on the gate layer; a passivation layer having first and second openings; a source electrode in contact with the electron supply layer via the first opening; and a drain electrode in contact with the electron supply layer via the second opening, wherein the gate layer is located between the first opening and the second opening, and wherein the gate layer includes a first gate layer of Ga-polar GaN and a second gate layer of N-polar GaN formed on the first gate layer.

### CROSS-REFERENCE TO RELATED APPLICATION

This application is based upon and claims the benefit of priority from Japanese Patent Application No. 2022-019438, filed on Feb. 10, 2022, the entire contents of which are incorporated herein by reference.

### TECHNICAL FIELD

The present disclosure relates to a nitride semiconductor device and a method of manufacturing the nitride semiconductor device.

### BACKGROUND

Currently, high electron mobility transistors (HEMTs) using nitride semiconductors are being commercialized. When an HEMT is applied to a power device, a normally-off operation that cuts off a current path (channel) between a source and a drain of the HEMT at zero bias is required from the viewpoint of fail-safe.

In a nitride semiconductor device, a heterojunction is formed by forming a second nitride semiconductor layer (electron supply layer), which has a bandgap (Al composition) different from that of a first nitride semiconductor layer (electron transit layer), on a first nitride semiconductor layer. Thus, a two-dimensional electron gas is formed in the first nitride semiconductor layer near an interface between the first nitride semiconductor layer and the second nitride semiconductor layer. Below a gate electrode, energy levels of the first nitride semiconductor layer and the second nitride semiconductor layer are raised by ionized acceptors contained in a gallium nitride (GaN) layer doped with acceptor-type impurities. As a result, an energy level of a conduction band at a heterojunction interface becomes higher than the Fermi level. Accordingly, when no bias is applied to the gate electrode, a channel of the two-dimensional electron gas is cut off immediately below the gate electrode, thereby realizing a normally-off type HEMT.

The performance of the HEMT using nitride semiconductors may deteriorate under a high-temperature environment due to thermal instability of the GaN layer that forms a gate layer under the gate electrode.

### SUMMARY

A nitride semiconductor device according to an aspect of the present disclosure includes: an electron transit layer composed of a nitride semiconductor; an electron supply layer formed on the electron transit layer and composed of a nitride semiconductor having a bandgap larger than that of the electron transit layer; a gate layer formed on a portion of the electron supply layer and composed of a nitride semiconductor containing acceptor-type impurities; a gate electrode formed on the gate layer; a passivation layer that covers the electron supply layer, the gate layer, and the gate electrode, and has a first opening and a second opening; a source electrode in contact with the electron supply layer via the first opening; and a drain electrode in contact with the electron supply layer via the second opening, wherein the gate layer is located between the first opening and the second opening, and wherein the gate layer includes a first gate layer of Ga-polar GaN and a second gate layer of N-polar GaN formed on the first gate layer.

A method of manufacturing a nitride semiconductor device according to another aspect of the present disclosure includes: forming an electron transit layer composed of a nitride semiconductor; forming an electron supply layer, which is composed of a nitride semiconductor having a bandgap larger than that of the electron transit layer, on the electron transit layer; forming a gate layer, which is composed of a nitride semiconductor containing acceptor-type impurities, on a portion of the electron supply layer; forming a gate electrode on the gate layer; forming a passivation layer that covers the electron supply layer, the gate layer, and the gate electrode, and has a first opening and a second opening; and forming a source electrode and a drain electrode that are in contact with the electron supply layer via the first opening and the second opening, respectively, wherein the gate layer is located between the first opening and the second opening, and wherein the gate layer includes a first gate layer of Ga-polar GaN and a second gate layer of N-polar GaN formed on the first gate layer.

### BRIEF DESCRIPTION OF DRAWINGS

The accompanying drawings, which are incorporated in and constitute a part of the specification, illustrate embodiments of the present disclosure.

FIG. 1 is a schematic cross-sectional view of an exemplary nitride semiconductor device according to a first embodiment.

FIG. 2 is a schematic cross-sectional view showing an exemplary manufacturing process of the nitride semiconductor device of FIG. 1.

FIG. 3 is a schematic cross-sectional view showing a manufacturing process subsequent to FIG. 2.

FIG. 4 is a schematic cross-sectional view showing a manufacturing process subsequent to FIG. 3.

FIG. 5 is a schematic cross-sectional view showing a manufacturing process subsequent to FIG. 4.

FIG. 6 is a schematic cross-sectional view showing a manufacturing process subsequent to FIG. 5.

FIG. 7 is a schematic cross-sectional view showing a manufacturing process subsequent to FIG. 6.

FIG. 8 is a schematic cross-sectional view showing a manufacturing process subsequent to FIG. 7.

FIG. 9 is a schematic cross-sectional view of an exemplary nitride semiconductor device according to a second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Some embodiments of a nitride semiconductor device of the present disclosure will be now described with reference to the accompanying drawings. It should be noted that, for simplicity and clarity of explanation, components shown in the drawings are not necessarily drawn to scale. In order to facilitate understanding, hatching lines may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is for illustrative purposes only and is not intended to limit the embodiments of the present disclosure or the applications and uses of such embodiments.

### First Embodiment

### (Basic Structure of Nitride Semiconductor Device)

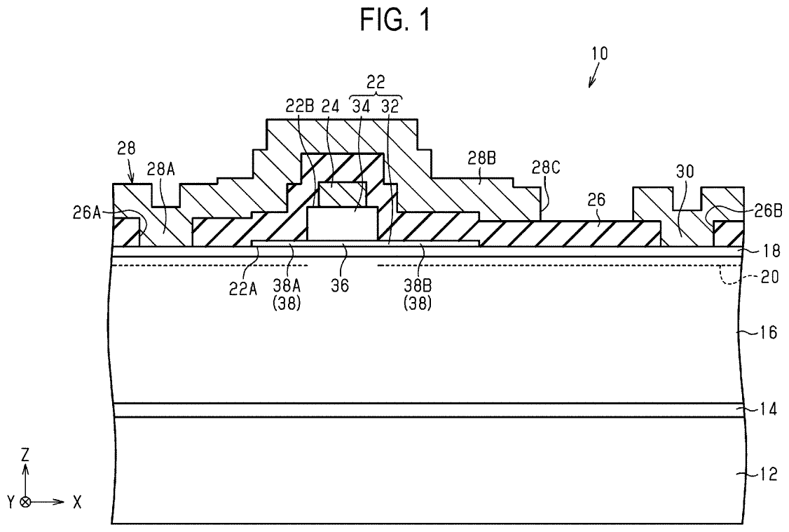

FIG. 1 is a schematic cross-sectional view of an exemplary nitride semiconductor device 10 according to a first embodiment. The nitride semiconductor device 10 may be, for example, a high electron mobility transistor (HEMT) using gallium nitride (GaN). The nitride semiconductor device 10 includes a semiconductor substrate 12, a buffer layer 14 formed on the semiconductor substrate 12, an electron transit layer 16 formed on the buffer layer 14, and an electron supply layer 18 formed on the electron transit layer 16.

The semiconductor substrate 12 may be made of silicon (Si), silicon carbide (SiC), GaN, sapphire, or other substrate materials. In one example, the semiconductor substrate 12 may be a Si substrate. A thickness of the semiconductor substrate 12 may be, for example, 200 μm or more and 1,500 μm or less. A Z-axis direction of mutually orthogonal XYZ axes shown in FIG. 1 is a direction orthogonal to a surface of the semiconductor substrate 12 on which a device is formed. The term “plan view” used in the present disclosure refers to viewing the nitride semiconductor device 10 from above along the Z-axis direction unless explicitly stated otherwise.

The buffer layer 14 may be located between the semiconductor substrate 12 and the electron transit layer 16. In one example, the buffer layer 14 may be composed of any material that can facilitate epitaxial growth of the electron transit layer 16. The buffer layer 14 may include one or more nitride semiconductor layers. In one example, the buffer layer 14 may include at least one selected from the group of an aluminum nitride (AlN) layer, an aluminum gallium nitride (AlGaN) layer, and a graded AlGaN layer having different aluminum (Al) compositions. For example, the buffer layer 14 may be formed by a single AlN layer, a single AlGaN layer, a layer having an AlGaN/GaN superlattice structure, a layer having an AlN/AlGaN superlattice structure, or a layer having an AlN/GaN superlattice structure.

In one example, the buffer layer 14 may include a first buffer layer that is an AlN layer formed on the semiconductor substrate 12, and a second buffer layer that is an AlGaN layer formed on the AlN layer. The first buffer layer may be, for example, an AlN layer having a thickness of 200 nm, while the second buffer layer may be formed, for example, by stacking an AlGaN layer with a thickness of 100 nm multiple times. Further, in order to suppress a leakage current in the buffer layer 14, impurities may be introduced into a portion of the buffer layer 14 to make the buffer layer 14 semi-insulating. In that case, the impurities are, for example, carbon (C) or iron (Fe), and a concentration of the impurity may be, for example, 4×10¹⁶ cm⁻³ or more.

The electron transit layer 16 is composed of a nitride semiconductor, and may be, for example, a GaN layer. A thickness of the electron transit layer 16 may be, for example, 0.5 μm or more and 2 μm or less. Further, in order to suppress a leakage current in the electron transit layer 16, impurities may be introduced into a portion of the electron transit layer 16 to make the electron transit layer 16 semi-insulating except for a surface layer region. In that case, the impurities are, for example, C, and a peak concentration of the impurities in the electron transit layer 16 may be, for example, 1×10¹⁹ cm⁻³ or more. That is, the electron transit layer 16 may include a plurality of GaN layers having different impurity concentrations, for example, a C-doped GaN layer and a non-doped GaN layer. In this case, the C-doped GaN layer is formed on the buffer layer 14 and may have a thickness of 0.3 μm to 2 μm. The C concentration in the C-doped GaN layer may be 9×10¹⁸ cm⁻³ or more and 9×10¹⁹ cm⁻³ or less. The non-doped GaN layer is formed on the C-doped GaN layer and may have a thickness of 0.05 μm or more and 0.3 μm or less. The non-doped GaN layer is in contact with the electron supply layer 18. In one example, the electron transit layer 16 includes a non-doped GaN layer having a thickness of 0.3 μm and a C-doped GaN layer having a thickness of 0.4 μm, and a concentration of C in the C-doped GaN layer may be approximately 5×10¹⁹ cm⁻³.

The electron supply layer 18 is composed of a nitride semiconductor having a bandgap larger than that of the electron transit layer 16, and may be, for example, an AlGaN layer. Since the bandgap increases as an Al composition increases, the electron supply layer 18, which is the AlGaN layer, has a bandgap larger than the electron transit layer 16 which is the GaN layer. In one example, the electron supply layer 18 is composed of AlₓGa₁₋ₓN, where x is 0.1<x<0.4, more specifically 0.2<x<0.3. The electron supply layer 18 may have a thickness of 5 nm or more and 20 nm or less. In one example, the electron supply layer 18 has a thickness of 8 nm or more.

The electron transit layer 16 and the electron supply layer 18 are composed of nitride semiconductors having different lattice constants. Therefore, the nitride semiconductor (for example, GaN) constituting the electron transit layer 16 and the nitride semiconductor (for example, AlGaN) constituting the electron supply layer 18 form a lattice-mismatched heterojunction. Due to spontaneous polarization of the electron transit layer 16 and the electron supply layer 18 and piezoelectric polarization caused by a stress received by the electron supply layer 18 near a heterojunction interface, an energy level of a conduction band of the electron transit layer 16 near the heterojunction interface becomes lower than the Fermi level. As a result, a two-dimensional electron gas (2DEG) 20 spreads in the electron transit layer 16 at a position near the heterojunction interface between the electron transit layer 16 and the electron supply layer 18 (for example, within a range of several nanometers from the interface). Further, by increasing at least one selected from the group of an Al composition and a thickness of the electron supply layer 18, a sheet carrier density of the 2DEG 20 generated in the electron transit layer 16 can be increased.

The nitride semiconductor device 10 further includes a gate layer 22 formed on the electron supply layer 18, a gate electrode 24 formed on the gate layer 22, and a passivation layer 26. The passivation layer 26 covers the electron supply layer 18, the gate layer 22, and the gate electrode 24, and has a first opening 26A and a second opening 26B. The nitride semiconductor device 10 may further include a source electrode 28 in contact with the electron supply layer 18 via the first opening 26A, and a drain electrode 30 in contact with the electron supply layer 18 via the second opening 26B.

Each of the first opening 26A and the second opening 26B of the passivation layer 26 is separated from the gate layer 22. The gate layer 22 may be located between the first opening 26A and the second opening 26B. More specifically, the gate layer 22 may be located between the first opening 26A and the second opening 26B and at a position closer to the first opening 26A than to the second opening 26B.

The gate layer 22 is formed on a portion of the electron supply layer 18 and is composed of a nitride semiconductor containing acceptor-type impurities. The gate layer 22 may be composed of any material having a smaller bandgap than the electron supply layer 18 which is, for example, an AlGaN layer. In the present embodiment, the gate layer 22 is composed of GaN (p-type GaN) containing acceptor-type impurities. The acceptor-type impurities may include magnesium (Mg). Further details of the gate layer 22 will be described later.

The gate electrode 24 may be formed on an upper surface 22B of the gate layer 22. The gate electrode 24 may be composed of one or more metal layers. In one example, the gate electrode 24 may be a titanium nitride (TiN) layer. In another example, the gate electrode 24 may be composed of a first metal layer made of Ti, and a second metal layer formed on the first metal layer and made of TiN. A thickness of the gate electrode 24 may be, for example, 50 nm or more and 200 nm or less. The gate electrode 24 may form a Schottky junction with the gate layer 22.

The source electrode 28 and the drain electrode 30 may be composed of one or more metal layers (for example, a combination of Ti layer, TiN layer, Al layer, AlSiCu layer, AlCu layer, etc.). At least a portion of the source electrode 28 is filled in the first opening 26A, so that it can come into ohmic contact with the 2DEG 20 immediately below the electron supply layer 18 via the first opening 26A. Similarly, at least a portion of the drain electrode 30 is filled in the second opening 26B, so that it can come into ohmic contact with the 2DEG 20 immediately below the electron supply layer 18 via the second opening 26B.

The source electrode 28 may include a source contact portion 28A filled in the first opening 26A, and a source field plate portion 28B covering the passivation layer 26. The source field plate portion 28B is continuous with the source contact portion 28A and is formed integrally with the source contact portion 28A. The source field plate portion 28B includes an end portion 28C located between the second opening 26B and the gate layer 22 in a plan view. The source field plate portion 28B extends along a surface of the passivation layer 26 from the source contact portion 28A to the end portion 28C toward the drain electrode 30, but is spaced apart from the drain electrode 30. The source field plate portion 28B extends along the non-flat surface of the passivation layer 26 and thus has a non-flat surface as well. When a drain voltage is applied to the drain electrode 30 in a zero bias state in which no gate voltage is applied to the gate electrode 24, the source field plate portion 28B plays a role of alleviating electric field concentration near an edge of the gate electrode 24.

### (Detailed Configuration of Gate Layer)

In the present embodiment, the gate layer 22 may include a first gate layer 32 of Ga-polar GaN and a second gate layer 34 of N-polar GaN formed on the first gate layer 32. The first gate layer 32 is in contact with the electron supply layer 18, while the second gate layer 34 is in contact with the gate electrode 24.

In a GaN crystal having a wurtzite structure, the crystal structure has asymmetry because Ga atoms and N atoms are arranged with a slight shift in the c-axis direction extending in the direction. This asymmetry causes polarization, and as a result, the c-plane ((0001) plane) of the GaN crystal becomes a polar plane. In general, GaN obtained by crystal growth in which the Ga-face becomes the outermost surface is called Ga-polar GaN, while GaN obtained by crystal growth in which the N-face becomes the outermost surface is called N-polar GaN.

The Ga-polar GaN and the N-polar GaN differ from each other in various properties. For example, the Ga-polar GaN is chemically very stable and has high etching resistance to a strong alkaline aqueous solution (for example, a potassium hydroxide aqueous solution). On the other hand, the N-polar GaN is less chemically stable than the Ga-polar GaN and is easily etched by the strong alkaline aqueous solution. The N-polar GaN has relatively low chemical stability, but is more stable under a high-temperature environment than the Ga-polar GaN. Moreover, a hexagonal pyramid-shaped or hexagon-shaped morphology is observed on a surface of the N-polar GaN.

A polarity of GaN can be switched by various methods. In one example, the polarity of GaN can be switched between Ga-polarity and N-polarity by adjusting an amount of magnesium doped during growth of GaN. More specifically, the polarity of GaN can be changed from Ga-polarity to N-polarity by increasing a concentration of the doped magnesium during growth of Ga-polar GaN.

In the present embodiment, the first gate layer 32 may contain magnesium having a concentration of 1×10¹⁸ cm⁻³ or more and less than 1×10²⁰ cm⁻³, as impurities. On the other hand, the second gate layer 34 may contain magnesium having a concentration of 1×10²⁰ cm⁻³ or more, as impurities. A concentration referred to herein means a peak concentration unless explicitly stated otherwise. An upper limit of magnesium concentration in the second gate layer 34 is determined by the amount of magnesium that can be doped into the GaN, and in one example, may be less than 1×10²¹ cm⁻³. However, the second gate layer 34 may contain magnesium having a concentration of 1×10²¹ cm⁻³ or more. The magnesium concentration in the second gate layer 34 is higher than the magnesium concentration in the first gate layer 32. In one example, the concentration of magnesium contained in the second gate layer 34 may be ten times or more the concentration of magnesium contained in the first gate layer 32. Optionally, the first gate layer 32 and/or the second gate layer 34 may contain acceptor-type impurities other than magnesium, such as zinc (Zn), carbon (C), or both.

The first gate layer 32 may be formed in a wider region than the second gate layer 34 in a plan view. More specifically, the first gate layer 32 may include a base portion 36 formed in the same region as the second gate layer 34 in a plan view, and an extension portion 38 extending outside the second gate layer 34 in a plan view. The base portion 36 may be formed integrally with the extension portion 38. Due to the presence of the extension portion 38, a bottom surface 22A of the gate layer 22 (a bottom surface of the first gate layer 32) may have an area larger than an upper surface 22B of the gate layer 22 (an upper surface of the second gate layer 34).

The extension portion 38 may include a source side portion 38A located between the second gate layer 34 and the first opening 26A in a plan view, and a drain side portion 38B located between the second gate layer 34 and the second opening 26B in a plan view. The source side portion 38A is adjacent to the base portion 36, and is located between the base portion 36 and the source contact portion 28A. The drain side portion 38B is adjacent to the base portion 36, and is located between the base portion 36 and the drain electrode 30. The source side portion 38A extends from the base portion 36 toward the first opening 26A, but is spaced apart from the first opening 26A. The drain side portion 38B extends from the base portion 36 toward the second opening 26B, but is spaced apart from the second opening 26B. In the example shown in FIG. 1, a length of the drain side portion 38B extending toward the second opening 26B may be greater than a length of the source side portion 38A extending toward the first opening 26A.

The thickest portion of the gate layer 22 including the base portion 36 of the first gate layer 32 and the second gate layer 34 may have a thickness of 80 nm or more and 150 nm or less. A thickness of the gate layer 22 may be determined in consideration of parameters including a gate threshold voltage. In one example, the gate layer 22 may have a thickness greater than 100 nm at its thickest portion, that is, a portion located below the gate electrode 24. On the other hand, the first gate layer 32 (or the extension portion 38) may have a thickness of 5 nm or more and 50 nm or less. More specifically, the first gate layer 32 (or the extension portion 38) may have a thickness of 5 nm or more and 25 nm or less.

### (Method of Manufacturing Nitride Semiconductor Device)

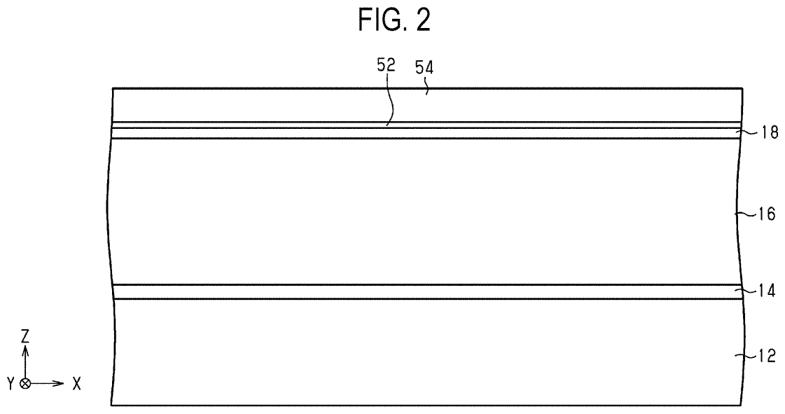

Next, an example of a method of manufacturing the nitride semiconductor device 10 of FIG. 1 will be described. The method of manufacturing the nitride semiconductor device 10 includes: forming the electron transit layer 16 composed of a nitride semiconductor; forming the electron supply layer 18 composed of a nitride semiconductor, which has a bandgap larger than that of the electron transit layer 16, on the electron transit layer 16; forming the gate layer 22 composed of a nitride semiconductor containing acceptor-type impurities on a portion of the electron supply layer 18; forming the gate electrode 24 on the gate layer 22; forming the passivation layer 26 that covers the electron supply layer 18, the gate layer 22, and the gate electrode 24 and has the first opening 26A and the second opening 26B; and forming the source electrode 28 and the drain electrode 30 that are in contact with the electron supply layer 18 via the first opening 26A and the second opening 26B, respectively. Details of the method of manufacturing the nitride semiconductor device 10 will be described below with reference to FIGS. 2 to 8.

FIGS. 2 to 8 are schematic cross-sectional views showing exemplary manufacturing processes of the nitride semiconductor device 10. In order to facilitate understanding, in FIGS. 2 to 8, the same components as those in FIG. 1 may be denoted by the same reference numerals.

As shown in FIG. 2, the manufacturing method includes forming the buffer layer 14, the electron transit layer 16, the electron supply layer 18, a first nitride semiconductor layer 52, and a second nitride semiconductor layer 54 sequentially on the semiconductor substrate 12 which is, for example, a Si substrate. The buffer layer 14, the electron transit layer 16, the electron supply layer 18, the first nitride semiconductor layer 52, and the second nitride semiconductor layer 54 may be epitaxially grown by metal organic chemical vapor deposition (MOCVD).

Although not shown in detail, in one example, the buffer layer 14 may be a multi-layered buffer layer. The multi-layered buffer layer may include an AlN layer (first buffer layer) formed on the semiconductor substrate 12, and a graded AlGaN layer (second buffer layer) formed on the AlN layer. The graded AlGaN layer may be formed, for example, by stacking three AlGaN layers having Al compositions of 75%, 50%, and 25% sequentially from a side close to the AlN layer.

The electron transit layer 16 formed on the buffer layer 14 may be a GaN layer. The electron supply layer 18 formed on the electron transit layer 16 may be an AlGaN layer. Therefore, the electron supply layer 18 is composed of a nitride semiconductor having a bandgap larger than that of the electron transit layer 16. In one example, the electron supply layer 18 has a thickness of 8 nm or more.

The first nitride semiconductor layer 52 formed on the electron supply layer 18 and the second nitride semiconductor layer 54 formed on the first nitride semiconductor layer 52 may be GaN layers containing magnesium as acceptor-type impurities. While growing GaN as the gate layer 22 on the electron supply layer 18, by changing the amount of magnesium doped into the gate layer 22, the first nitride semiconductor layer 52 of Ga-polar GaN and the second nitride semiconductor layer 54 of N-polar GaN can be formed. The amount of magnesium doped into the GaN layer can be changed by controlling a flow rate of a doping gas (for example, biscyclopentadienylmagnesium (Cp₂Mg)) introduced into a growth chamber, a growth temperature, and the like.

In the present embodiment, the polarity of GaN is changed from Ga polarity to N polarity by increasing the amount of magnesium doped during the growth of the gate layer 22. As a result, the second nitride semiconductor layer 54 of N-polar GaN can be formed on the first nitride semiconductor layer 52 of Ga-polar GaN formed on the electron supply layer 18.

Further, the first nitride semiconductor layer 52 of Ga-polar GaN may be formed to have a desired thickness by adjusting a timing of changing the amount of magnesium to be doped. For example, the first nitride semiconductor layer 52 can be made thicker by delaying the timing of increasing the amount of magnesium to be doped. On the other hand, the first nitride semiconductor layer 52 can be made thinner by advancing the timing of increasing the amount of magnesium to be doped.

The concentration of magnesium contained in the second nitride semiconductor layer 54 may be ten times or more the concentration of magnesium contained in the first nitride semiconductor layer 52. In one example, the first nitride semiconductor layer 52 may contain magnesium having a concentration of 1×10¹⁸ cm⁻³ or more and less than 1×10²⁰ cm⁻³, as impurities, and the second nitride semiconductor layer 54 can contain magnesium having a concentration of 1×10²⁰ cm⁻³ or more, as impurities. Further, the total thickness of the first nitride semiconductor layer 52 and the second nitride semiconductor layer 54 may be greater than 100 nm, and the first nitride semiconductor layer 52 may have a thickness of 5 nm or more and 50 nm or less.

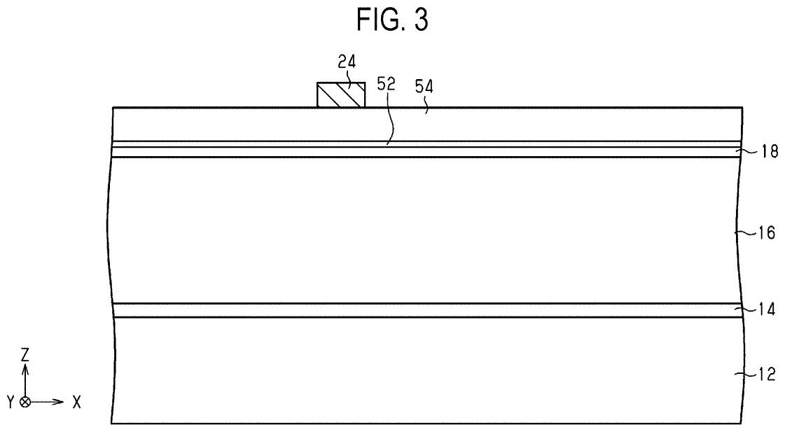

FIG. 3 is a schematic cross-sectional view showing a manufacturing process subsequent to FIG. 2. As shown in FIG. 3, the manufacturing method further includes forming the gate electrode 24. The gate electrode 24 may be formed, for example, by forming a metal layer (not shown) such as a TiN layer on the second nitride semiconductor layer 54 by sputtering, and then selectively removing the metal layer by lithography and etching.

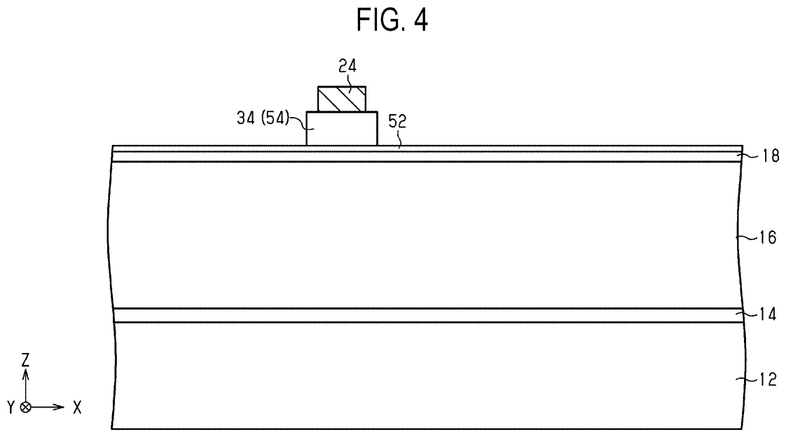

FIG. 4 is a schematic cross-sectional view showing a manufacturing process subsequent to FIG. 3. As shown in FIG. 4, the manufacturing method further includes patterning the second nitride semiconductor layer 54 by lithography and etching to form the second gate layer 34. In one example, a mask (not shown) is formed to cover upper and side surfaces of the gate electrode 24, and the second nitride semiconductor layer 54 is etched using this mask.

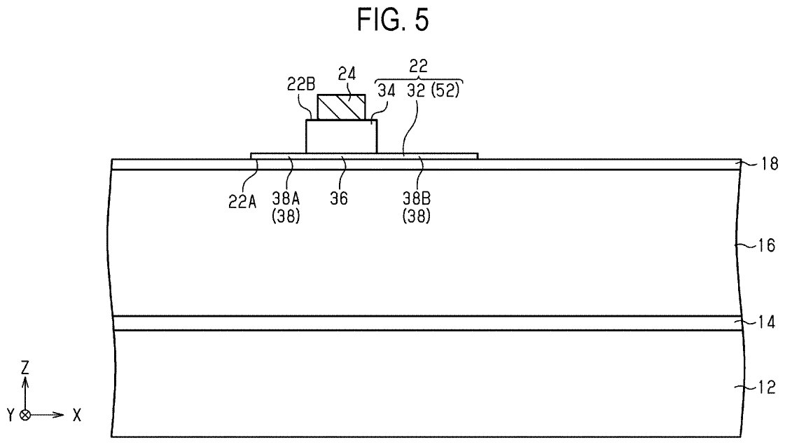

In the present embodiment, the second gate layer 34 may be formed by selectively removing the second nitride semiconductor layer 54 by wet-etching using a strong alkaline aqueous solution (for example, potassium hydroxide aqueous solution) as an etchant. In this case, the second nitride semiconductor layer 54 of N-polar GaN is relatively easily etched by the strong alkaline aqueous solution, whereas the first nitride semiconductor layer 52 of Ga-polar GaN is hardly etched. Therefore, the etching in this process can be stopped at a point of time when the first nitride semiconductor layer 52 is exposed. As a result, it is possible to easily control a thickness of the first gate layer 32 formed from the first nitride semiconductor layer 52 in the subsequent process shown in FIG. 5.

FIG. 5 is a schematic cross-sectional view showing a manufacturing process subsequent to FIG. 4. As shown in FIG. 5, the manufacturing method further includes patterning the first nitride semiconductor layer 52 by lithography and etching to form the first gate layer 32. Since the first gate layer 32 includes the extension portion 38, the first gate layer 32 is formed in a wider region than the second gate layer 34 in a plan view. In one example, a mask (not shown) is formed to cover the gate electrode 24, the second gate layer 34, and a portion of the first nitride semiconductor layer 52 corresponding to the extension portion 38, and then the first nitride semiconductor layer 52 is etched using this mask. In one example, the first gate layer 32 may be formed by selectively removing the first nitride semiconductor layer 52 by dry-etching. As a result, a portion of the electron supply layer 18 that is not covered with the gate layer 22 (the first gate layer 32) is exposed. The exposed electron supply layer 18 may almost be unetched in this process. Alternatively, in another example, the exposed electron supply layer 18 may be overetched. In that case, the exposed portion of the electron supply layer 18 may have a thickness smaller than that of a portion covered by the first gate layer 32.

Through the process described above, the gate layer 22 including the first gate layer 32 of Ga-polar GaN and the second gate layer 34 of N-polar GaN formed on the first gate layer 32 is formed. The concentration of magnesium contained in the second gate layer 34 may be ten times or more the concentration of magnesium contained in the first gate layer 32. In one example, the first gate layer 32 contains magnesium having a concentration of 1×10¹⁸ cm⁻³ or more and less than 1×10²⁰ cm⁻³, as impurities, and the second gate layer 34 contains magnesium having a concentration of 1×10²⁰ cm⁻³ or more, as impurities.

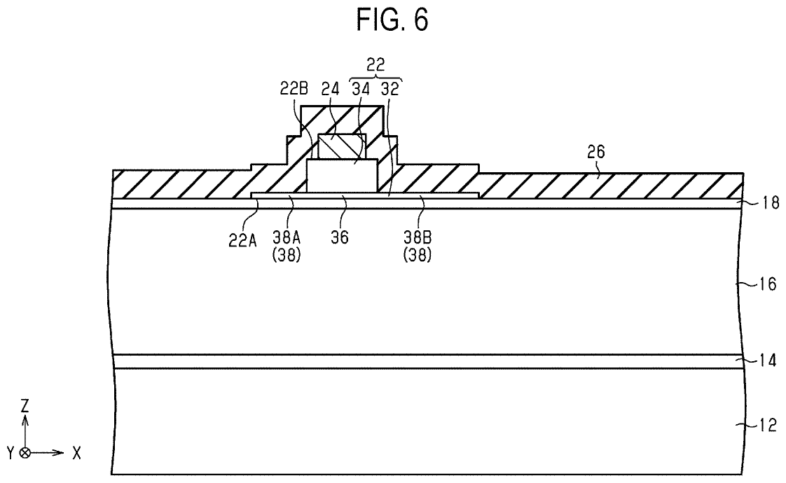

FIG. 6 is a schematic cross-sectional view showing a manufacturing process subsequent to FIG. 5. As shown in FIG. 6, the manufacturing method further includes forming the passivation layer 26 so as to entirely cover the exposed surfaces of the electron supply layer 18, the first gate layer 32, the second gate layer 34, and the gate electrode 24. In one example, the passivation layer 26 may be a SiN layer formed by a low-pressure CVD (Low-Pressure Chemical Vapor Deposition, LPCVD) method.

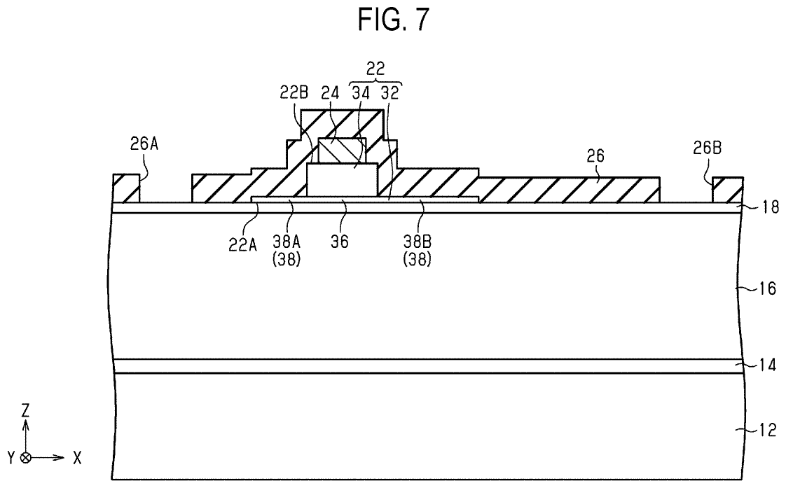

FIG. 7 is a schematic cross-sectional view showing a manufacturing process subsequent to FIG. 6. As shown in FIG. 7, the manufacturing method further includes selectively removing the passivation layer 26 by lithography and etching to form the first opening 26A and the second opening 26B. The first opening 26A and the second opening 26B are formed such that the gate layer 22 is located between the first opening 26A and the second opening 26B. The gate layer 22 may be located closer to the first opening 26A than the second opening 26B.

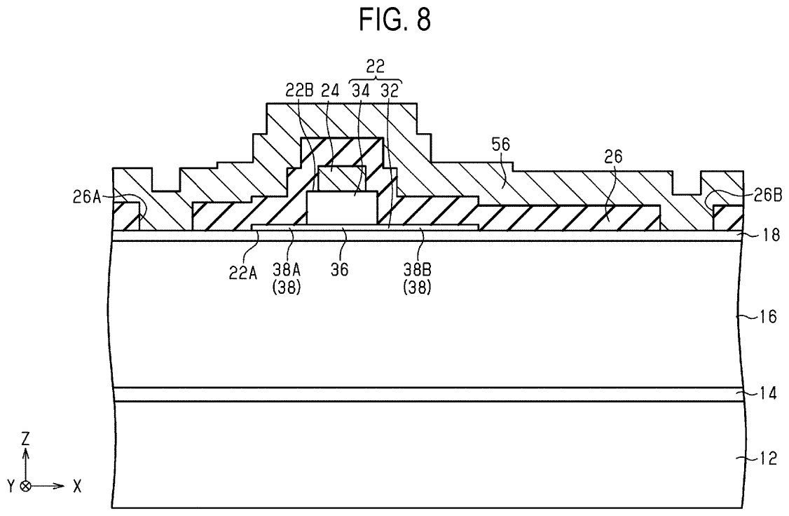

FIG. 8 is a schematic cross-sectional view showing a manufacturing process subsequent to FIG. 7. As shown in FIG. 8, the manufacturing method further includes forming a metal layer 56 that fills the first opening 26A and the second opening 26B, and additionally covers the passivation layer 26. In one example, the metal layer 56 may include at least one selected from the group of a Ti layer, a TiN layer, an Al layer, an AlSiCu layer, and an AlCu layer.

The manufacturing method further includes selectively removing the metal layer 56 by lithography and etching to form the source electrode 28 and the drain electrode 30 shown in FIG. 1. As a result, the nitride semiconductor device 10 shown in FIG. 1 can be obtained.

### (Operations of Nitride Semiconductor Device)

Operations of the nitride semiconductor device 10 of the present embodiment will be described below.

When a voltage exceeding a threshold voltage is applied to the gate electrode 24 of the nitride semiconductor device 10, a channel is formed by the 2DEG 20 in the electron transit layer 16 to make electrical conduction between the source and the drain. On the other hand, at zero bias, the 2DEG 20 is not formed in at least a portion of a region of the electron transit layer 16 located below the gate layer 22. This is because the gate layer 22 contains acceptor-type impurities, so that the energy levels of the electron transit layer 16 and the electron supply layer 18 are raised and thus the 2DEG 20 is depleted. With this configuration, a normally-off operation of the nitride semiconductor device 10 is implemented.

In the nitride semiconductor device 10, the gate electrode 24 and the gate layer 22 are Schottky-junctioned to form an energy barrier at an interface between the gate electrode 24 and the gate layer 22, and a gate withstand voltage is maintained by this energy barrier and an energy barrier of the electron supply layer 18. However, when an excessive positive bias is applied to the gate electrode 24 due to some external factor such as influence of a parasitic inductance, holes are injected from the gate electrode 24 into the gate layer 22 and are accumulated at an interface between the gate layer 22 and the electron supply layer 18.

In the present embodiment, since the first gate layer 32 spreads over a wider region than the second gate layer 34 in a plan view due to the presence of the extension portion 38, a density of holes accumulated at the interface between the gate layer 22 and the electron supply layer 18 can be reduced. Therefore, band bending of the electron supply layer 18 caused by the accumulation of the holes can be suppressed, and an increase in gate leakage current can be suppressed.

Here, when a thickness of the extension portion 38 is excessively large, the on-resistance is increased by a decrease of the 2DEG 20, causing a problem such as hindering the depletion layer from extending from the source field plate portion 28B. Therefore, it is important to be able to stably form the extension portion 38 having a desired thickness.

In this respect, according to the nitride semiconductor device 10 of the present embodiment, since the first gate layer 32 is Ga-polar GaN and the second gate layer 34 is N-polar GaN, the extension portion 38 can be stably formed using a difference in chemical stability between the first gate layer 32 and the second gate layer 34 due to the polarity of GaN. This also contributes to improving the yield of the nitride semiconductor device 10.

The extension portion 38 may be formed by wet-etching the second gate layer 34 and then dry-etching the first gate layer 32. The thickness of the extension portion 38 is determined by a thickness of the first gate layer 32 exposed after wet-etching the second gate layer 34. Here, when the second gate layer 34 of N-polar GaN with relatively low chemical stability is wet-etched, the etching stops at the first gate layer 32 of Ga-polar GaN with relatively high chemical stability. Therefore, in the epitaxial growth of the gate layer 22, by adjusting the thickness of the first gate layer 32 of Ga-polar GaN, the extension portion 38 having a desired thickness can be stably formed. Further, the second gate layer 34 can be formed into a desired shape relatively easily by wet-etching.

Further, since N-polar GaN has higher thermal stability than Ga-polar GaN, when the gate layer 22 includes the second gate layer 34 of N-polar GaN, performance deterioration of the nitride semiconductor device 10 under a high-temperature environment can be suppressed.

The nitride semiconductor device 10 of the first embodiment has the following advantages.

(1) Since the gate layer 22 includes the second gate layer 34 of N-polar GaN, performance deterioration of the nitride semiconductor device 10 under a high-temperature environment can be suppressed.

(2) The gate layer 22 includes the first gate layer 32 of Ga-polar GaN and the second gate layer 34 of N-polar GaN formed on the first gate layer 32, and the first gate layer 32 includes the extension portion 38 extending outside the second gate layer 34 in a plan view. As a result, the extension portion 38 can be stably formed using the difference in chemical stability between the first gate layer 32 and the second gate layer 34 due to the polarity of GaN.

Further, since the first gate layer 32 spreads over a wider region than the second gate layer 34 in a plan view due to the presence of the extension portion 38, the density of holes accumulated at the interface between the gate layer 22 and the electron supply layer 18 can be reduced. Therefore, band bending of the electron supply layer 18 caused by the accumulation of the holes can be suppressed, and an increase in gate leakage current can be suppressed.

(3) The concentration of magnesium contained in the second gate layer 34 may be ten times or more the concentration of magnesium contained in the first gate layer 32. As a result, inversion from Ga polarity to N polarity occurs quickly during the growth of GaN for the gate layer 22, and therefore, the thickness of the first gate layer 32 can be easily adjusted.

(4) The gate layer 22 is located closer to the first opening 26A than the second opening 26B. As a result, since a distance between the gate electrode 24 and the drain electrode 30 can be relatively increased, dielectric breakdown between the gate and the drain, to which a relatively large voltage is likely to be applied, can be suppressed.

(5) The source electrode 28 includes the source contact portion 28A that fills the first opening 26A, and the source field plate portion 28B that covers the passivation layer 26, and the source field plate portion 28B may include the end portion 28C located between the gate electrode 24 and the second opening 26B in a plan view.

In a turn-off state of a transistor, when a high voltage is applied between the drain and the source, electrons are trapped in crystal defects or layer interfaces inside the transistor, for example, inside an electron transit layer or on a surface of an electron supply layer, and the electrons thereof inhibit a two-dimensional electron gas from being generated. In this case, it is known that the on-resistance increases when the transistor is switched later to a turn-on state, and this phenomenon is called current collapse.

According to the configuration described above, since the depletion layer can be extended from the source field plate portion 28B toward the 2DEG 20, occurrence of current collapse can be suppressed.

(6) The gate layer 22 may have a thickness greater than 100 nm, the first gate layer 32 may have a thickness of 5 nm or more and 50 nm or less, and the electron supply layer 18 may have a thickness of 8 nm or more. According to this configuration, in the nitride semiconductor device 10, a maximum rating of a gate-source voltage during positive bias can be improved.

### Second Embodiment

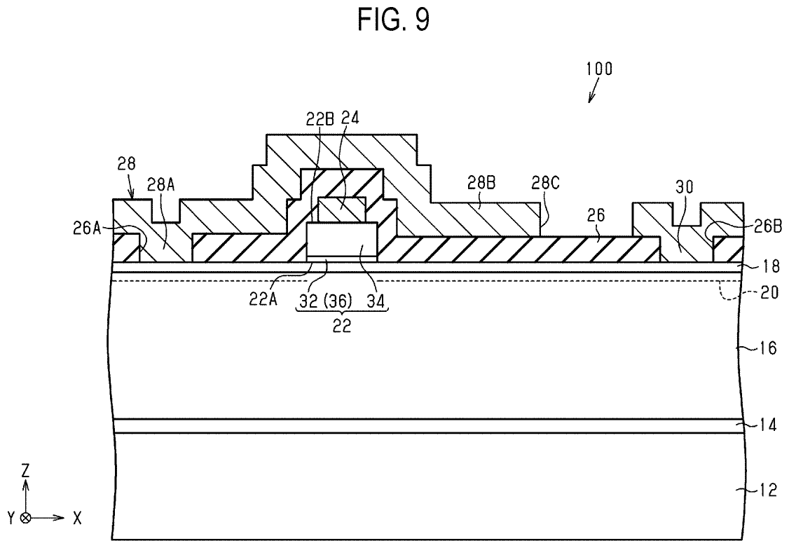

FIG. 9 is a schematic cross-sectional view of an exemplary nitride semiconductor device 100 according to a second embodiment. In FIG. 9, the same components as those of the nitride semiconductor device 10 according to the first embodiment are denoted by the same reference numerals. Further, detailed explanation of the same components as in the first embodiment will be omitted.

The nitride semiconductor device 100 according to the second embodiment shown in FIG. 9 is different from the nitride semiconductor device 10 according to the first embodiment shown in FIG. 1 in that the first gate layer 32 included in the gate layer 22 does not include the extension portion 38 shown in FIG. 1, but includes only the base portion 36. Therefore, the first gate layer 32 and the second gate layer 34 are formed in the same region in a plan view.

Also in the second embodiment, since the gate layer 22 includes the second gate layer 34 of N-polar GaN, performance deterioration of the nitride semiconductor device 100 under a high-temperature environment can be suppressed.

Further, in the second embodiment, the gate layer 22 is formed by wet-etching N-polar GaN using Ga-polar GaN as an etching stop layer first, and then dry-etching the Ga-polar GaN. As a result, for example, process damage to the exposed electron supply layer 18 can be reduced as compared with a case where the gate layer made of only Ga-polar GaN is formed without using an etching stop layer.

The process damage to the electron supply layer 18 can promote the above-mentioned current collapse. Therefore, by forming the second gate layer 34 of N-polar GaN by wet-etching first and then forming the first gate layer 32 of Ga-polar GaN by dry-etching, the occurrence of current collapse in the nitride semiconductor device 100 can be suppressed. This is also applied to the nitride semiconductor device 10 according to the first embodiment.

### [Modifications]

The above-described embodiments can be modified and implemented as follows.

The first gate layer 32 may be an undoped layer. The term “undoped layer” as used in the present disclosure is defined as a layer into which impurities have not been intentionally introduced. Even when the first gate layer 32 is the undoped layer, the nitride semiconductor device 10 can perform the normally-off operation, because the second gate layer 34 contains magnesium as acceptor-type impurities. Further, since the first gate layer 32 is the undoped layer, an increase in on-resistance of the nitride semiconductor device 10 can be suppressed.

The gate layer 22 may further include an intermediate layer located between the first gate layer 32 and the second gate layer 34. The intermediate layer may contain both Ga-polar GaN and N-polar GaN.

Although the gate electrode 24 is illustrated as being formed on a portion of the upper surface 22B of the gate layer 22, the gate electrode 24 may be formed so as to cover the entire upper surface 22B of the gate layer 22.

An additional wiring layer may be formed on a layer including the source electrode 28 and the drain electrode 30.

One or more of the various examples described herein can be combined as long as they are not technically inconsistent.

The term “on” as used in the present disclosure includes the meanings of “on” and “above” unless clearly stated otherwise in the context. Therefore, the expression “a first layer is formed on a second layer” is intended that in some embodiments, the first layer may be directly arranged on the second layer in contact with the second layer, and in other embodiments, the first layer may be arranged above the second layer without contacting the second layer. That is, the term “on” does not exclude a structure in which other layers are formed between the first and second layers. For example, the structure in which the electron supply layer 18 is formed on the electron transit layer 16 may include a structure in which an intermediate layer is located between the electron supply layer 18 and the electron transit layer 16 in order to form the 2DEG 20 stably.

The terms indicating directions such as “vertical,” “horizontal,” “upward,” “downward,” “upper,” “lower,” “forward,” “backward,” “lateral,” “left-hand side,” “right-hand side,” “front,” “back,” and the like, as used in the present disclosure depend on a particular orientation of a described and illustrated device. A variety of alternative orientations can be envisioned in the present disclosure, and thus these directional terms should not be interpreted narrowly.

For example, the z-axis direction used in the present disclosure does not necessarily have to be the vertical direction, and it does not have to be exactly the same as the vertical direction. Therefore, in various structures (for example, the structure shown in FIG. 1) according to the present disclosure, “upper” and “lower” in the Z-axis direction described herein are not limited to “upper” and “lower” in the vertical direction. For example, the X-axis direction may be the vertical direction, or the Y-axis direction may be the vertical direction.

### [Supplementary Notes]

The technical ideas that can be recognized from the present disclosure are described below. In addition, for the purpose of aiding understanding and not for the purpose of limitation, components described in Supplementary Notes are labeled with the reference numerals of the corresponding components in the embodiments. The reference numerals are provided as examples to aid understanding, and the components described in Supplementary Notes should not be limited to the components indicated by the reference numerals.

### (Supplementary Note 1)

A nitride semiconductor device including:

an electron transit layer (16) composed of a nitride semiconductor;

an electron supply layer (18) formed on the electron transit layer (16) and composed of a nitride semiconductor having a bandgap larger than that of the electron transit layer (16);

a gate layer (22) formed on a portion of the electron supply layer (18) and composed of a nitride semiconductor containing acceptor-type impurities;

a gate electrode (24) formed on the gate layer (22);

a passivation layer (26) that covers the electron supply layer (18), the gate layer (22), and the gate electrode (24), and has a first opening (26A) and a second opening (26B);

a source electrode (28) in contact with the electron supply layer (18) via the first opening (26A); and

a drain electrode (30) in contact with the electron supply layer (18) via the second opening (26B),

wherein the gate layer (22) is located between the first opening (26A) and the second opening (26B), and

wherein the gate layer (22) includes a first gate layer (32) of Ga-polar GaN and a second gate layer (34) of N-polar GaN formed on the first gate layer (32).

### (Supplementary Note 2)

The nitride semiconductor device (10) of Supplementary Note 1, wherein the first gate layer (32) includes an extension portion (38) extending outside the second gate layer (34) in a plan view.

### (Supplementary Note 3)

The nitride semiconductor device of Supplementary Note 2, wherein the extension portion (38) includes:

a source side portion (38A) located between the second gate layer (34) and the first opening (26A) in a plan view; and

a drain side portion (38B) located between the second gate layer (34) and the second opening (26B) in a plan view.

### (Supplementary Note 4)

The nitride semiconductor device of any one of Supplementary Notes 1 to 3, wherein the first gate layer (32) contains magnesium having a concentration of 1×10¹⁸ cm⁻³ or more and less than 1×10²⁰ cm⁻³, as impurities, and

wherein the second gate layer (34) contains magnesium having a concentration of 1×10²⁰ cm⁻³ or more, as impurities.

### (Supplementary Note 5)

The nitride semiconductor device of Supplementary Note 4, wherein the concentration of magnesium contained in the second gate layer (34) is ten times or more the concentration of magnesium contained in the first gate layer (32).

### (Supplementary Note 6)

The nitride semiconductor device of any one of Supplementary Notes 1 to 5, wherein the gate layer (22) is located closer to the first opening (26A) than the second opening (26B).

### (Supplementary Note 7)

The nitride semiconductor device of any one of Supplementary Notes 1 to 6, wherein the source electrode (28) includes a source contact portion (28A) that is filled in the first opening (26A), and a source field plate portion (28B) that covers the passivation layer (26), and the source field plate portion (28B) includes an end portion (28C) located between the gate electrode (24) and the second opening (26B) in a plan view.

### (Supplementary Note 8)

The nitride semiconductor device of any one of Supplementary Notes 1 to 7, wherein the electron transit layer (16) is GaN, and

wherein the electron supply layer (18) is AlₓGa₁₋ₓN, where 0.2<x<0.3.

### (Supplementary Note 9)

The nitride semiconductor device of any one of Supplementary Notes 1 to 8, wherein the gate layer (22) has a thickness greater than 100 nm, the first gate layer (32) has a thickness of 5 nm or more and 50 nm or less, and the electron supply layer (18) has a thickness of 8 nm or more.

### (Supplementary Note 10)

A method of manufacturing a nitride semiconductor device, including:

forming an electron transit layer (16) composed of a nitride semiconductor;

forming an electron supply layer (18), which is composed of a nitride semiconductor having a bandgap larger than that of the electron transit layer (16), on the electron transit layer (16);

forming a gate layer (22), which is composed of a nitride semiconductor containing acceptor-type impurities, on a portion of the electron supply layer (18);

forming a gate electrode (24) on the gate layer (22);

forming a passivation layer (26) that covers the electron supply layer (18), the gate layer (22), and the gate electrode (24), and has a first opening (26A) and a second opening (26B); and

forming a source electrode (28) and a drain electrode (30) that are in contact with the electron supply layer (18) via the first opening (26A) and the second opening (26B), respectively,

wherein the gate layer (22) is located between the first opening (26A) and the second opening (26B), and

wherein the gate layer (22) includes a first gate layer (32) of Ga-polar GaN and a second gate layer (34) of N-polar GaN formed on the first gate layer (32).

### (Supplementary Note 11)

The method of Supplementary Note 10, wherein the first gate layer (32) includes an extension portion (38) extending outside the second gate layer (34) in a plan view.

### (Supplementary Note 12)

The method of Supplementary Note 10 or 11, wherein the act of forming the gate layer (22) includes forming a first nitride semiconductor layer (52) of Ga-polar GaN and a second nitride semiconductor layer (54) of N-polar GaN by changing an amount of magnesium doped into the gate layer (22) while growing GaN as the gate layer (22) on the electron supply layer (18).

### (Supplementary Note 13)

The method of Supplementary Note 12, wherein the act of forming the gate layer (22) further includes:

forming the second gate layer (34) by selectively removing the second nitride semiconductor layer (54) by wet-etching; and

forming the first gate layer (32) by selectively removing the first nitride semiconductor layer (52) by dry-etching.

### (Supplementary Note 14)

The method of any one of Supplementary Notes 10 to 13, wherein the first gate layer (32) contains magnesium having a concentration of 1×10¹⁸ cm⁻³ or more and less than 1×10²⁰ cm⁻³, as impurities, and

wherein the second gate layer (34) contains magnesium having a concentration of 1×10²⁰ cm⁻³ or more, as impurities.

### (Supplementary Note 15)

The method of Supplementary Note 14, wherein the concentration of magnesium contained in the second gate layer (34) is ten times or more the concentration of magnesium contained in the first gate layer (32).

### (Supplementary Note 16)

The method of any one of Supplementary Notes 10 to 15, wherein the gate layer (22) is located closer to the first opening (26A) than the second opening (26B).

### (Supplementary Note 17)

The method of any one of Supplementary Notes 10 to 16, wherein the source electrode (28) includes a source contact portion (28A) that is filled in the first opening (26A), and a source field plate portion (28B) that covers the passivation layer (26), and the source field plate portion (28B) includes an end portion (28C) located between the gate electrode (24) and the second opening (26B) in a plan view.

### (Supplementary Note 18)

The method of any one of Supplementary Notes 10 to 17, wherein the electron transit layer (16) is GaN, and

wherein the electron supply layer (18) is AlₓGa₁₋ₓN, where 0.2<x<0.3.

### (Supplementary Note 19)

The method of any one of Supplementary Notes 10 to 18, wherein the gate layer (22) has a thickness greater than 100 nm, the first gate layer (32) has a thickness of 5 nm or more and 50 nm or less, and the electron supply layer (18) has a thickness of 8 nm or more.

The above description is merely an example. Those skilled in the art will appreciate that more possible combinations and substitutions are possible beyond the components and methods (manufacturing processes) enumerated for the purposes of illustrating the techniques of the present disclosure. The present disclosure is intended to cover all alternatives, modifications, and changes that fall within the scope of the present disclosure, including the claims.

According to the present disclosure in some embodiments, it is possible to suppress deterioration in performance of a nitride semiconductor device under a high-temperature environment.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A nitride semiconductor device comprising:
an electron transit layer composed of a nitride semiconductor;
an electron supply layer formed on the electron transit layer and composed of a nitride semiconductor having a bandgap larger than that of the electron transit layer;
a gate layer formed on a portion of the electron supply layer and composed of a nitride semiconductor containing acceptor-type impurities;
a gate electrode formed on the gate layer;
a passivation layer that covers the electron supply layer, the gate layer, and the gate electrode, and has a first opening and a second opening;
a source electrode in contact with the electron supply layer via the first opening; and
a drain electrode in contact with the electron supply layer via the second opening,
wherein the gate layer is located between the first opening and the second opening, and
wherein the gate layer includes a first gate layer of Ga-polar GaN and a second gate layer of N-polar GaN formed on the first gate layer.

2. The nitride semiconductor device of claim 1, wherein the first gate layer includes an extension portion extending outside the second gate layer in a plan view.

3. The nitride semiconductor device of claim 2, wherein the extension portion includes:
a source side portion located between the second gate layer and the first opening in a plan view; and
a drain side portion located between the second gate layer and the second opening in a plan view.

4. The nitride semiconductor device of claim 1, wherein the first gate layer contains magnesium having a concentration of 1×10¹⁸ cm⁻³ or more and less than 1×10²⁰ cm⁻³, as impurities, and
wherein the second gate layer contains magnesium having a concentration of 1×10²⁰ cm⁻³ or more, as impurities.

5. The nitride semiconductor device of claim 4, wherein the concentration of magnesium contained in the second gate layer is ten times or more the concentration of magnesium contained in the first gate layer.

6. The nitride semiconductor device of claim 1, wherein the gate layer is located closer to the first opening than the second opening.

7. The nitride semiconductor device of claim 1, wherein the source electrode includes a source contact portion that is filled in the first opening, and a source field plate portion that covers the passivation layer, and the source field plate portion includes an end portion located between the gate electrode and the second opening in a plan view.

8. The nitride semiconductor device of claim 1, wherein the electron transit layer is GaN, and
wherein the electron supply layer is AlₓGa₁₋ₓN, where 0.2<x<0.3.

9. The nitride semiconductor device of claim 1, wherein the gate layer has a thickness greater than 100 nm, the first gate layer has a thickness of 5 nm or more and 50 nm or less, and the electron supply layer has a thickness of 8 nm or more.

10. A method of manufacturing a nitride semiconductor device, comprising:
forming an electron transit layer composed of a nitride semiconductor;
forming an electron supply layer, which is composed of a nitride semiconductor having a bandgap larger than that of the electron transit layer, on the electron transit layer;
forming a gate layer, which is composed of a nitride semiconductor containing acceptor-type impurities, on a portion of the electron supply layer;
forming a gate electrode on the gate layer;
forming a passivation layer that covers the electron supply layer, the gate layer, and the gate electrode, and has a first opening and a second opening; and
forming a source electrode and a drain electrode that are in contact with the electron supply layer via the first opening and the second opening, respectively,
wherein the gate layer is located between the first opening and the second opening, and
wherein the gate layer includes a first gate layer of Ga-polar GaN and a second gate layer of N-polar GaN formed on the first gate layer.

11. The method of claim 10, wherein the first gate layer includes an extension portion extending outside the second gate layer in a plan view.

12. The method of claim 10, wherein the act of forming the gate layer includes forming a first nitride semiconductor layer of Ga-polar GaN and a second nitride semiconductor layer of N-polar GaN by changing an amount of magnesium doped into the gate layer while growing GaN as the gate layer on the electron supply layer.

13. The method of claim 12, wherein the act of forming the gate layer further includes:
forming the second gate layer by selectively removing the second nitride semiconductor layer by wet-etching; and
forming the first gate layer by selectively removing the first nitride semiconductor layer by dry-etching.

14. The method of claim 10, wherein the first gate layer contains magnesium having a concentration of 1×10¹⁸ cm⁻³ or more and less than 1×10²⁰ cm⁻³, as impurities, and wherein the second gate layer contains magnesium having a concentration of 1×10²⁰ cm⁻³ or more, as impurities.

15. The method of claim 14, wherein the concentration of magnesium contained in the second gate layer is ten times or more the concentration of magnesium contained in the first gate layer.
